(19) United States
(12) Patent Application Publication
(10) Pub. No.: US 2004/0120175 A1
(43) Pub. Date: Jun. 24, 2004

(54) Space-efficient transistor cascode array

(76) Inventors: Gerhard Schrom, Hillsboro, OR (US); Krishnamurthy Soumyanath, Portland, OR (US)

Correspondence Address: BUCKLEY, MASCHOFF, TALWALKAR LLC, 5 ELM STREET, NEW CANAAN, CT, 06840, US

(21) Appl. No.: 10/326,697

(22) Filed: Dec. 20, 2002

(51) Int. Cl. G11C 5/06; G11C 5/02

(52) U.S. Cl. 365/51; 365/63

(57) ABSTRACT

A semiconductor cascode structure includes a plurality of source contacts located in a first diffusion region. The first diffusion region is substantially surrounded by a first gate region. The cascode structure also includes a plurality of drain contacts located in a second diffusion region. The second diffusion region is substantially surrounded by a second gate region.

### BACKGROUND

A cascode is a conventional circuit arrangement in which two transistors are connected in series, i.e. with the drain of one transistor coupled to the source of another. Cascodes are frequently employed to reduce capacitance effects. One common application of cascodes is in amplifiers.

Conventional techniques for fabricating semiconductor cascodes may be disadvantageous in that such techniques may not efficiently utilize semiconductor substrate space.

### BRIEF DESCRIPTION OF THE DRAWINGS

FIG. 1 is a schematic circuit diagram showing a conventional cascode arrangement.

FIG. 2 is a schematic plan view showing the layout of a transistor cascode cell according to some embodiments.

FIG. 3 is a schematic cross-sectional view of a gate region of the transistor cascode cell of FIG. 2.

FIG. 4 is a schematic plan view of a semiconductor cascode structure formed according to some embodiments from cascode cells like the cell shown in FIG. 2.

FIG. 5 is a schematic plan view which shows an alternative layout of source contacts provided according to some embodiments for the cascode structure of FIG. 4.

FIG. 6 is a schematic diagram showing connections of metallization layers provided according to some embodiments in association with the cascode structure of FIG. 4.

FIG. 7 is a schematic plan view showing a layout of a first metal layer provided according to some embodiments in association with a cascode structure having the source contact layout of FIG. 5.

FIG. 8 is a schematic plan view showing respective layouts of the first metal layer shown in FIG. 7 and a second metal layer provided according to some embodiments.

FIG. 9 is a simplified schematic plan view showing portions of the second metal layer of FIG. 8 on a larger scale.

FIG. 10 is a simplified block diagram which shows a circuit that incorporates a transistor cascode structure provided in accordance with some embodiments.

### DETAILED DESCRIPTION

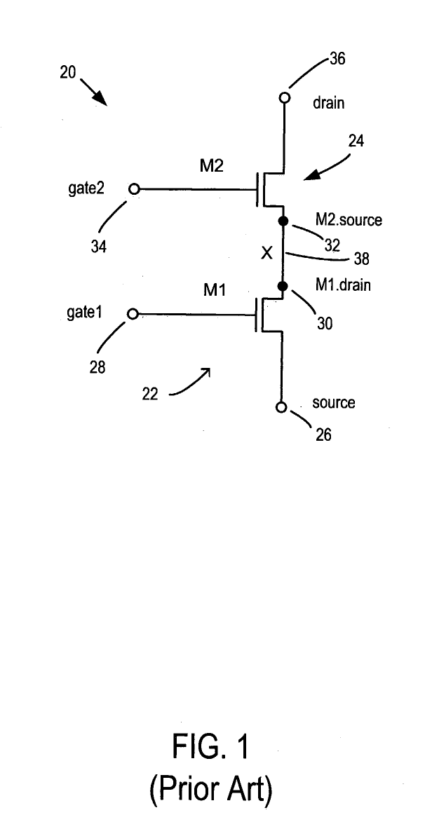

FIG. 1 is a schematic circuit diagram showing a conventional cascode arrangement. The cascode 20 illustrated in FIG. 1 is formed from two FETs (field effect transistors), namely transistor M1 (reference numeral 22) and transistor M2 (reference numeral 24). The transistor 22 has a source terminal 26, a gate terminal 28 (gate1), and a drain terminal 30. The transistor 24 has a source terminal 32, a gate terminal 34 (gate2), and a drain terminal 36. The drain terminal 30 of the transistor 22 is coupled to the source terminal 32 of the transistor 24. Typically, the transistor 22 is formed of a first diffusion region corresponding to its source, a second diffusion region corresponding to its drain, and a gate region between the first and second diffusion regions. The transistor 24 is formed of a third diffusion region corresponding to its source, a fourth diffusion region corresponding to its drain, and a second gate region between the third and fourth diffusion regions. (The diffusion regions and the gate regions are not separately shown.) The coupling of the drain of transistor 22 to the source of transistor 24 may be provided by a metal interconnect 38 between the second and third diffusion regions. (The interconnection between the two transistors is also indicated by an “x” in the drawing.) Viewed from the outside, the cascode 20 may be considered a four-terminal device, including a source terminal (source terminal 26 of transistor 22), a first gate terminal (“gate1”, also indicated as gate terminal 28 of transistor 22), a second gate terminal (“gate2”, also indicated as gate terminal 34 of transistor 24), and a drain terminal (drain terminal 36 of transistor 24).

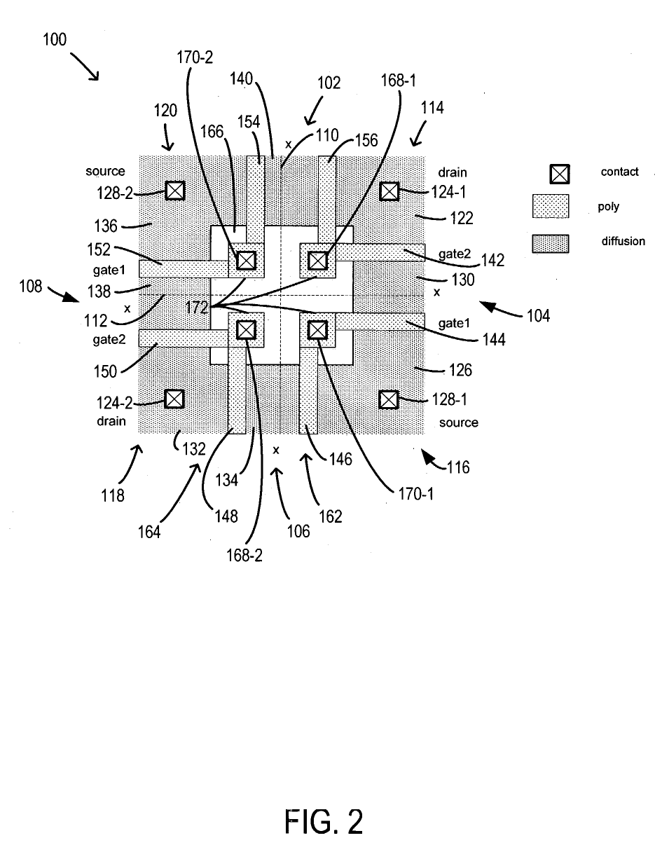

FIG. 2 is a schematic plan view showing a layout of a transistor cascode cell 100 according to some embodiments of the invention. The cascode cell 100 provides four cascodes 102, 104, 106, 108 in a highly space-efficient arrangement. The cascode cell 100 may be divided into four quadrants by dashed lines 110, 112. The four quadrants include a first quadrant (upper right-hand quadrant 114), a second quadrant (lower right-hand quadrant 116), a third quadrant (lower left-hand quadrant 118) and a fourth quadrant (upper left-hand quadrant 120).

The cascode cell 100 includes a first diffusion region 122 in the first quadrant 114, and a first drain contact 124-1 located in the first diffusion region. The cascode cell 100 also includes a second diffusion region 126 in the second quadrant 116, and a first source contact 128-1 located in the second diffusion region. Also included in the cascode cell 100 is a third diffusion region 130 located between the first diffusion region 122 and the second diffusion region 126. The cascode cell 100 further includes a fourth diffusion region 132 in the third quadrant 118, and a second drain contact 124-2 located in the fourth diffusion region. Also included in the cascode cell 100 is a fifth diffusion region 134 located between the second diffusion region 126 and the fourth diffusion region 132. The cascode cell 100 further includes a sixth diffusion region 136 in the fourth quadrant 120, and a second source contact 128-2 located in the sixth diffusion region. Also included in the cascode cell 100 are a seventh diffusion region 138 located between the fourth diffusion region 132 and the sixth diffusion region 136, and an eighth diffusion region 140 located between the first diffusion region 122 and the sixth diffusion region 136.

The cascode cell 100 further includes:

(1) a first gate region 142 located in the first quadrant 114 between the first diffusion region 122 and the third diffusion region 130;

(2) a second gate region 144 located in the second quadrant 116 between the second diffusion region 126 and the third diffusion region 130;

(3) a third gate region 146 located in the second quadrant 116 between the second diffusion region 126 and the fifth diffusion region 134;

(4) a fourth gate region 148 located in the third quadrant 118 between the fourth diffusion region 132 and the fifth diffusion region 134;

(5) a fifth gate region 150 located in the third quadrant 118 between the fourth diffusion region 132 and the seventh diffusion region 138;

(6) a sixth gate region 152 located in the fourth quadrant 120 between the sixth diffusion region 136 and the seventh diffusion region 138;

(7) a seventh gate region 154 located in the fourth quadrant 120 between the sixth diffusion region 136 and the eighth diffusion region 140; and

(8) an eighth gate region 156 located in the first quadrant 114 between the first diffusion region 122 and the eighth diffusion region 140.

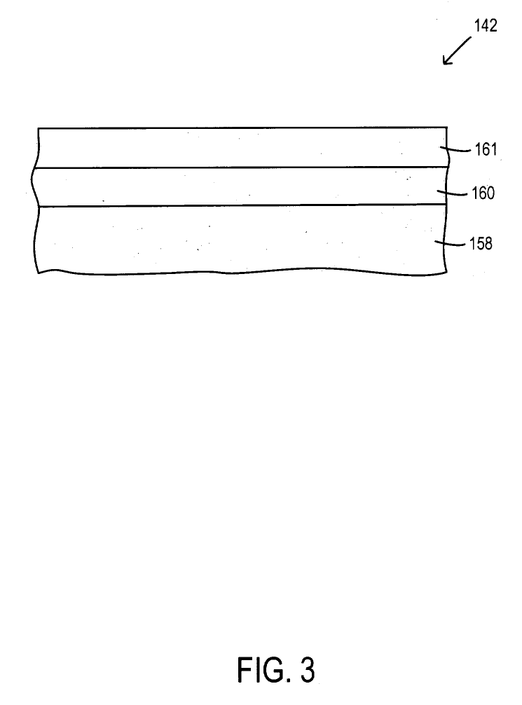

FIG. 3 is a schematic cross-sectional view of a typical one of the first through eighth gate regions, say first gate region 142. The gate region includes a substrate 158 of a first conductivity type, on which an insulation layer 160 is formed. A polysilicon gate layer 161 is formed on the insulation layer. The same structure shown in FIG. 3 may be present in each of the first through eighth gate regions.

The diffusion regions 122, 126, 130, 132, 134, 136, 138 and 140 may all be of a second conductivity type that is different from the first conductivity type. For example, the substrate 158 may be P-type, and the diffusion regions 122, 126, 130, 132, 134, 136, 138 and 140 may be N-type. Taking the cascode 106 as an example, the second diffusion region 126, the third gate region 146 and the fifth diffusion region 134 form a first field effect transistor 162 of the cascode 106, and the fifth diffusion region 134, the fourth gate region 148 and the fourth diffusion region 132 form a second field effect transistor 164 of the cascode 106. The drain (not separately shown) of the FET 162 is coupled to the source (not separately shown) of the FET 164, by virtue of the FETs 162, 164 sharing the fifth diffusion region 134. Like cascode 106, the other cascodes 102, 104, 108 of the cascode cell 100 are each formed of two FETs having the drain of one FET coupled to the source of the other FET by a shared diffusion region. The shared diffusion regions 130, 134, 138 and 140 are all marked with an “x” in the drawing to signify that this is a point of interconnection between the two FETs of a cascode.

The cascode cell 100 further includes an isolation region 166 which overlaps a respective portion of each of the quadrants 114, 116, 118, 120 and which borders the first through eighth diffusion regions and the first through eighth gate regions. The isolation region 166 may be substantially square in profile. Also included in the cascode cell 100 are:

(1) a first gate contact 168-1 located in the isolation region 166 and in the first quadrant 114, and coupled to the first gate region 142 and to the eighth gate region 156;

(2) a second gate contact 170-1 located in the isolation region 166 and in the second quadrant 116, and coupled to the second gate region 144 and to the third gate region 146;

(3) a third gate contact 168-2 located in the isolation region 166 and in the third quadrant 118, and coupled to the fourth gate region 148 and to the fifth gate region 150; and

(4) a fourth gate contact 170-2 located in the isolation region 166 and in the fourth quadrant 120, and coupled to the sixth gate region 152 and to the seventh gate region 154.

The gate contacts are coupled to polysilicon gate layers 161 of their respective gate regions by respective polysilicon regions 172.

The second gate contact 170-1 is shared by the cascodes 104, 106 and serves as a first gate terminal (gate1) for both cascodes 104 and 106. The fourth gate contact 170-2 is shared by the cascodes 102, 108 and serves as a first gate terminal (gate1) for both cascodes 102 and 108. The first gate contact 168-1 is shared by the cascodes 102, 104 and serves as a second gate terminal (gate2) for both cascodes 102 and 104. The third gate contact 168-2 is shared by the cascodes 106, 108 and serves as a second gate terminal (gate2) for both cascodes 106 and 108.

The first drain contact 124-1 and the first diffusion region 122 are shared by the cascodes 102, 104 and the first drain contact 124-1 serves as a drain terminal for both cascodes 102, 104. The second drain contact 124-2 and the fourth diffusion region 132 are shared by the cascodes 106, 108 and the second drain contact 124-2 serves as a drain terminal for both cascodes 106, 108. The first source contact 128-1 and the second diffusion region 126 are shared by the cascodes 104, 106 and the first source contact 128-1 serves as a source terminal for both cascodes 104, 106. The second source contact 128-2 and the sixth diffusion region 136 are shared by the cascodes 102, 108 and the second source contact 128-2 serves as a source terminal for both cascodes 102, 108.

The gate regions 142, 144, 146, 148, 150, 152, 154 and 156 may be positioned off-center relative to their respective gate contacts 168 or 170 (as the case may be), as shown in FIG. 2. More specifically, the “gate2” regions may be shifted closer to the nearest drain contact 124, and the “gate 1” regions may be shifted farther from the nearest source contact 128. This has the effect of causing the source diffusion areas 126, 136 to be larger than the drain diffusion areas 122, 132. The source diffusion areas may be substantially equal in size to each other, and the drain diffusion areas may be substantially equal in size to each other. All four of the shared diffusion areas 130, 134, 138 and 140 may be substantially equal in size to each other, and each of the shared diffusion areas may be smaller than each of the drain diffusion areas. Each of the gate regions may be smaller than each of the shared diffusion regions.

The positioning of the gates closer to the drain than to the source may be advantageous in that it may tend to reduce capacitance at the drain. However, the gates need not be so positioned, and the relative sizes of the drain, source and shared diffusion regions may be varied. As will be seen, another possible advantage of source diffusion regions that are larger than drain diffusion regions may be that a larger source diffusion region may facilitate placement of additional source contacts in the source diffusion region. This may provide the advantage of reducing the resistance at the source terminal of the cascode structure.

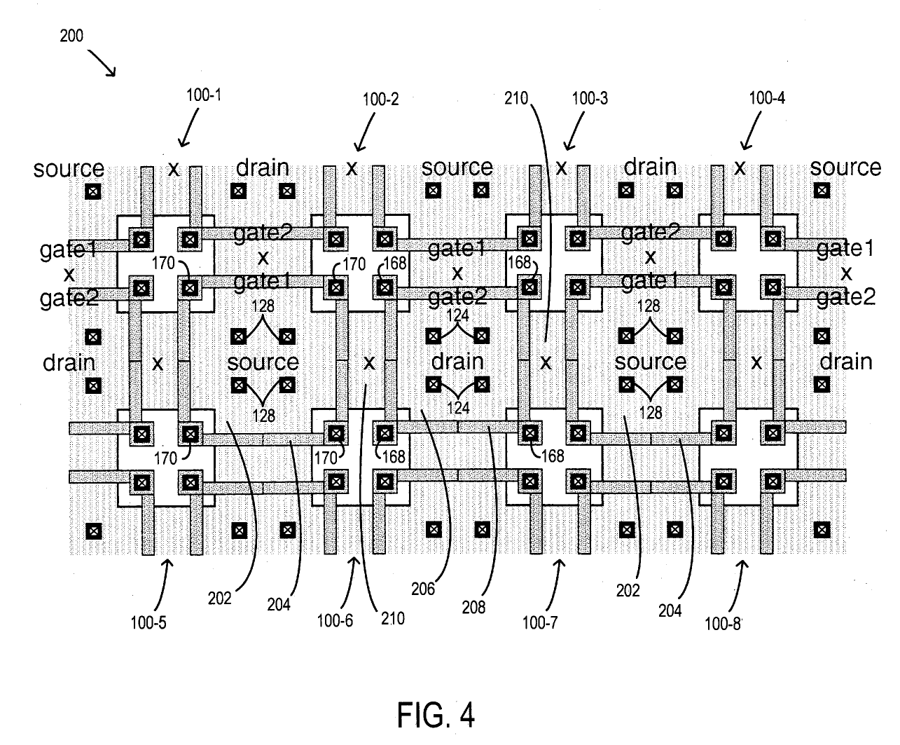

FIG. 4 is a partial schematic plan view of a semiconductor cascode structure 200 formed as an array of cells like the cell 100 shown in FIG. 2. In particular, of the eight cells shown in FIG. 4, cells 100-1, 100-3, 100-5 and 100-7 have the same layout as the cell shown in FIG. 2, whereas the other cells 100-2, 100-4, 100-6 and 100-8 have a layout that is the mirror image of the cell shown in FIG. 2. More generally, in both the rows and columns of an array formed of the cells, the cells may alternate between a first layout and a mirror image of the first layout, so that like diffusion and gate regions of adjacent cells may be joined together.

In the particular example shown in FIG. 4, the array of cells is formed with two rows and four columns. In some embodiments, an array of 12 rows by four columns or four rows by 12 columns may be employed to provide an effective channel width of about 110 nm. Alternatively, other array sizes, including larger arrays and/or other ratios of column size to row size may be provided.

In the cascode structure 200 shown in FIG. 4, substantially square source diffusion regions 202, are formed jointly by juxtaposition of respective source diffusion regions of four adjoining cells (i.e., cells 100-1, 100-2, 100-5 and 100-6; or cells 100-3, 100-4, 100-7 and 100-8). Four source contacts 128 are located in each source diffusion region 202. Each source diffusion region 202 is substantially surrounded by a respective gate region 204 which corresponds to a first gate terminal (not separately shown) of the cascode structure 200. The gate region 204 is generally in the form of a hollow square and is formed by respective “gate1” regions of the respective group of four adjoining cells which forms the source diffusion region 202.

Substantially square drain diffusion regions 206 (of which only one is shown in FIG. 4) are also formed in the cascode structure 200 by juxtaposition of respective drain diffusion regions of four adjoining cells (i.e., cells 100-2, 100-3, 100-6 and 100-7). Four drain contacts 124 are located in the drain diffusion region 206. The drain diffusion region 206 is substantially surrounded by a gate region 208 which corresponds to a second gate terminal (not separately shown) of the cascode structure 200. The gate region 208 is generally in the form of a hollow square and is formed by respective “gate2” regions of the four adjoining cells 100-2, 100-3, 100-5 and 100-6. A shared diffusion region 210 may be formed between each pair of a source diffusion region 202 and a drain diffusion region 206. More specifically, a shared diffusion region 210 may be formed between the respective gate regions 204 and 208 which surround the diffusion regions.

In some embodiments, the source diffusion regions 202 may be larger than the drain diffusion regions 206, and the drain diffusion regions may be larger than the shared diffusion regions 210.

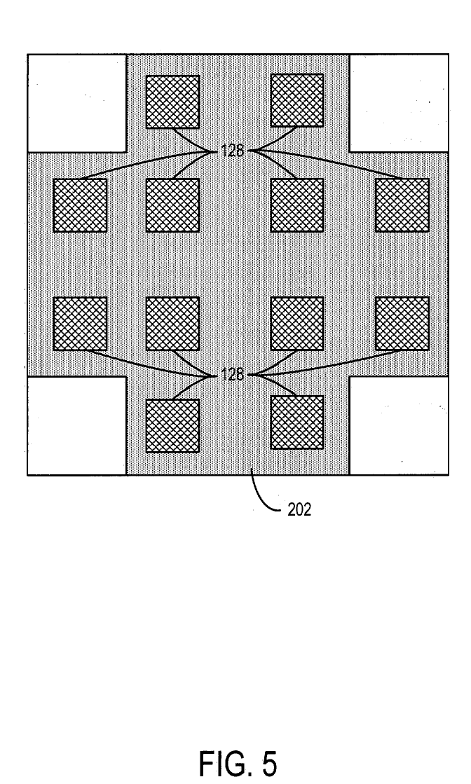

FIG. 5 is a schematic plan view that shows a layout of source contacts 128 in a source diffusion region 202 provided in accordance with some alternative embodiments. It will be noted that in the layout of FIG. 5, 12 source contacts 128 are located in the diffusion region 202. As indicated above, the increased number of source contacts may reduce the source resistance. The layout of FIG. 5 could be achieved by modifying the cell 100 of FIG. 2 by providing three source contacts 128 in each diffusion region 126, 136 instead of the single source contact shown in each source diffusion region in FIG. 2. The modified cell could then be employed in the array shown in FIG. 4 instead of the cell shown in FIG. 2. In general the number of contacts per diffusion region can be increased and/or locations of the source and drain contacts in the source and drain diffusion regions can be readily modified.

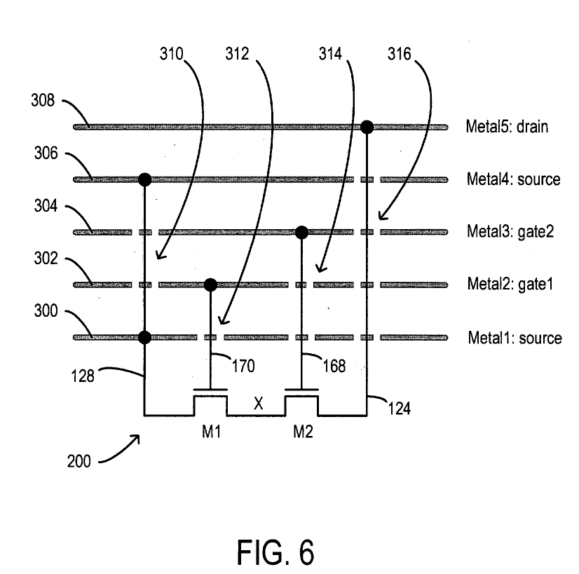

FIG. 6 is a schematic diagram showing a metallization scheme employed in accordance with some embodiments in association with the cascode structure of FIG. 4. In FIG. 6 the cascode structure 200 is schematically represented as a single cascode having a source contact 128, a first gate contact 170, a second gate contact 168 and a drain contact 124. In the metallization scheme of FIG. 6, all source contacts of the cascode structure 200 of FIG. 4 (whether or not modified in accordance with FIG. 5) are coupled together; all drain contacts of the cascode structure are coupled together; all “gate 1” contacts of the cascode structure are coupled together; and all “gate2” contacts of the cascode structure are coupled together. As a result the cascode structure functions as a single cascode with multiple signal paths connected in parallel.

The metallization scheme of FIG. 6 comprises five metal layers including a first metal layer 300, a second metal layer 302, a third metal layer 304, a fourth metal layer 306, and a fifth metal layer 308.

The first metal layer 300 is used for local interconnection for source contacts and for “gate2” contacts, as described in more detail below. Other functions of the metal layer 300 will also be described below.

The second metal layer 302 is used to connect in parallel all “gate1” contacts (reference numeral 170, FIGS. 2 and 4). The third metal layer 304 is used to connect in parallel all “gate2” contacts (reference numeral 168, FIGS. 2 and 4). The fourth metal layer 306 is used to connect in parallel all source contacts (reference numeral 128 in FIGS. 2, 4 and 5). The fifth metal layer 308 is used to connect in parallel all drain contacts (reference numeral 124 in FIGS. 2 and 4).

The metallization scheme shown in FIG. 6 also includes:

(1) A via stack 310 to couple the source contacts to the fourth metal layer 306;

(2) A via stack 312 to couple the “gate1” contacts to the second metal layer 302;

(3) A via stack 314 to couple the “gate2” contacts to the third metal layer 304; and

(4) A via stack 316 to couple the drain contacts to the fifth metal layer 308.

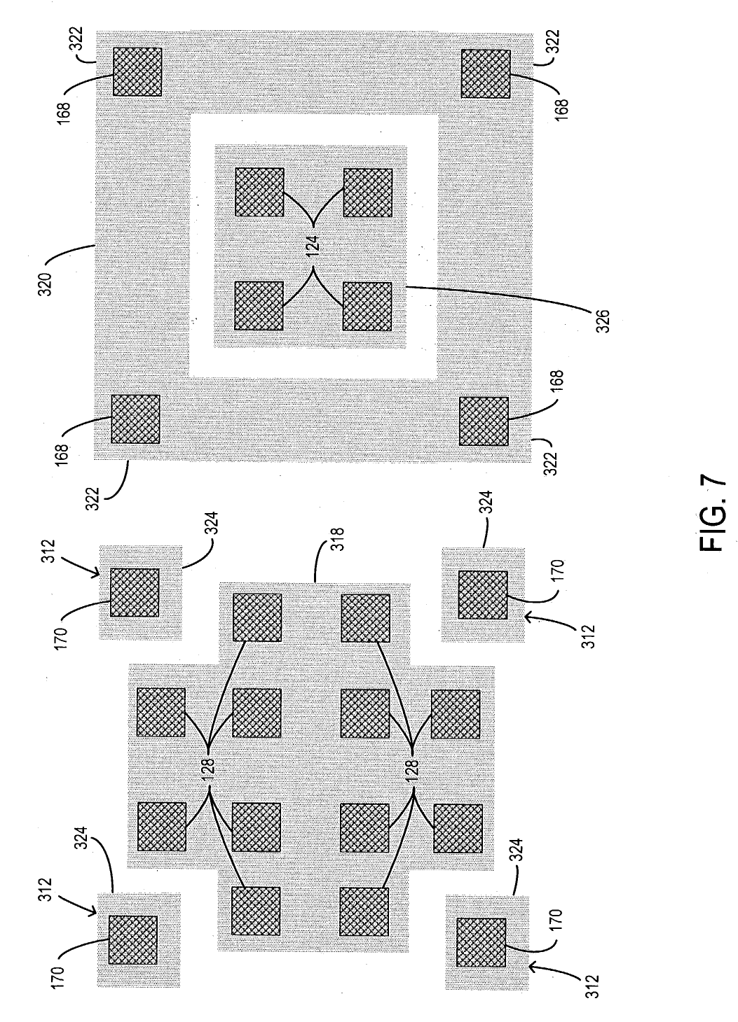

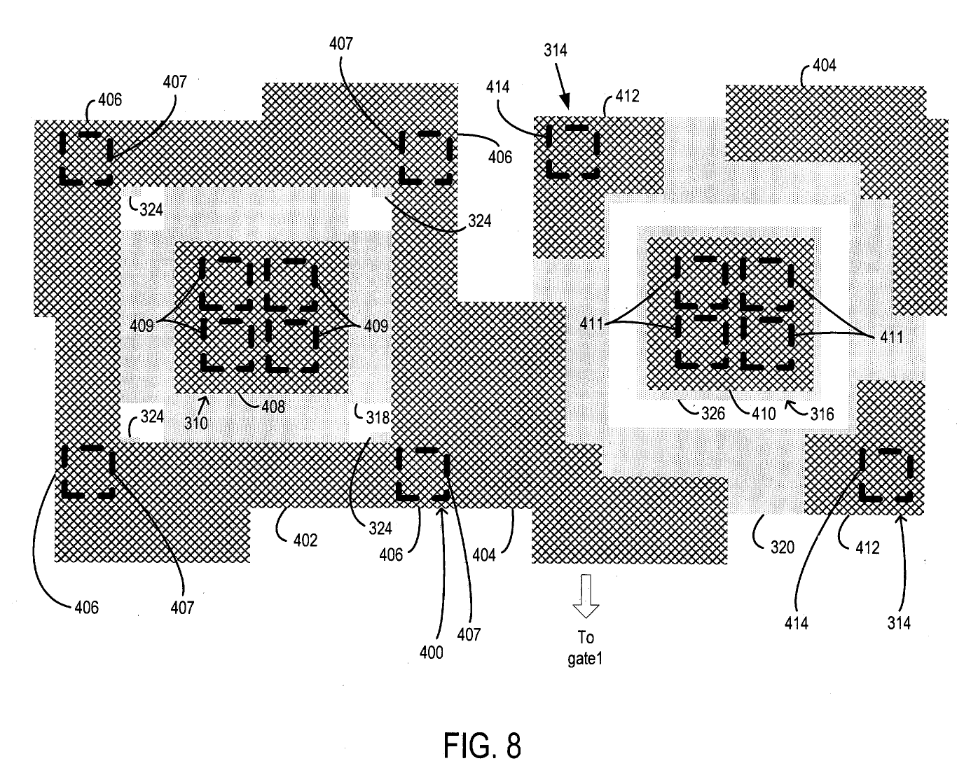

FIG. 7 is a schematic plan view that shows some details of the first metal layer 300. For the purposes of FIG. 7 (as well as the following FIG. 8), it is assumed that the layout of FIG. 5 is employed for the source contacts 128. In FIG. 7, the shaded areas correspond to the first metal layer 300, and the cross-hatched squares represent the contacts shown in FIGS. 4 and 5.

The first metal layer includes a first metal region 318 which interconnects (i.e., provides local interconnection for) the source contacts 128 located in a source diffusion region 202 (FIG. 4, not indicated in FIG. 7). The first metal layer also includes a second metal region 320 which provides a local interconnection for four “gate2” contacts 168. The second metal region 320 has a profile in the shape of a hollow square, which is coupled at each of its four corners 322 to a respective “gate2” contact 168. (Instead of a hollow square, the second metal region 320 may alternatively have the profile of a hollow non-square rectangle.)

Also included in the first metal layer are: (a) a third metal region 326 that interconnects and forms part of the via stack 316 for the drain contacts 124; and (b) metal regions 324 that form part of the via stacks 312 for the “gate1” contacts 170. It will be noted that the second metal region 320 surrounds the third metal region 326.

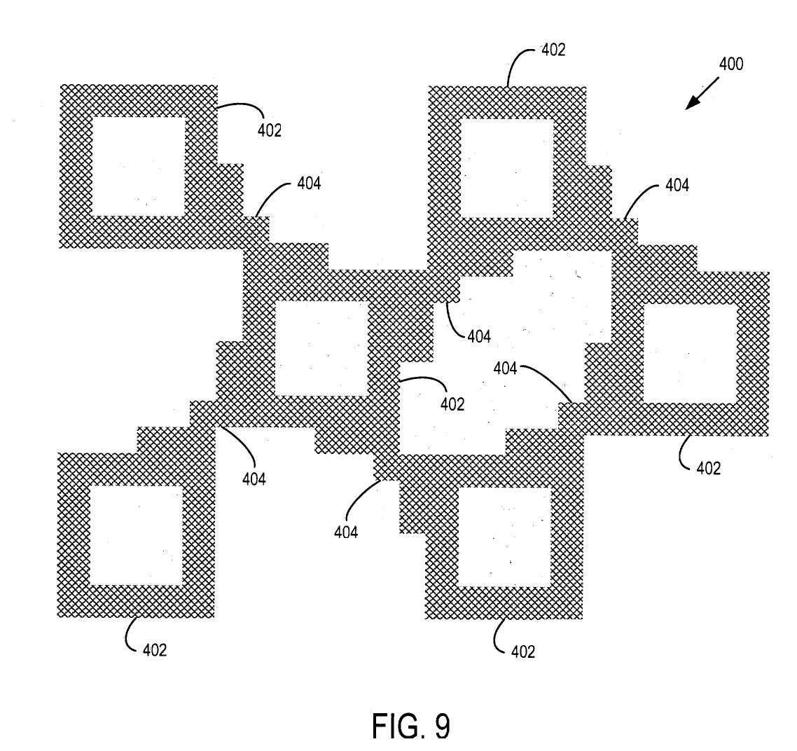

FIG. 8 is a schematic plan view that shows some details of the second metal layer 302. FIG. 9 is another schematic plan view showing only some features of the second metal layer on a larger scale. In FIGS. 8 and 9, the cross-hatched areas correspond to the second metal layer 302, and the shaded areas (only shown in FIG. 8) correspond to the first metal layer as shown in FIG. 7. No contacts are shown in FIGS. 8 and 9, but the layout of the second metal layer can be understood in relation to the contacts and to the first metal layer, by reference to the shaded areas (first metal layer), which appear in both FIGS. 7 and 8. The dashed line squares in FIG. 8 indicate vias that interconnect the first and second metal layers.

The second metal layer partially overlies the first metal layer, and includes a continuous region 400 (which is the only portion of the second metal layer that is shown in FIG. 9). The continuous region 400 includes interconnect regions 402 and bridge regions 404 that serve to connect the interconnect regions 402 to form a plane or web that covers the entire extent of the cascode array structure served by the second metal layer. (FIG. 9 is only a partial representation of the continuous region 400, and does not show additional interconnect regions and bridge regions that may connect the interconnect regions shown in the drawing to additional interconnect regions that are not shown.) Each interconnect region 400 is generally in the shape of a hollow square, with four corners 406 (FIG. 8), each of which is coupled through the first metal layer (and specifically through the via stack 312, which includes vias 407, and the region 324 of the first metal layer) to a respective “gate1” contact 170 (FIGS. 4 and 7, not shown in FIG. 8). Thus the continuous region 400 of the second metal layer serves to provide a parallel connection for all of the “gate1” contacts of the entire cascode structure.

Continuing to refer to FIG. 8, the second metal layer also includes a metal region 408 (omitted from FIG. 9), which is surrounded by the interconnect region 402 and which is coupled to the region 318 of the first metal layer to form part of the via stack 310 (including vias 409) for the source contacts 128 (not shown in FIG. 8). Also included in the second metal layer is a metal region 410 (omitted from FIG. 9), which is coupled to the metal region 326 of the first metal layer to form part of the via stack 316 (including vias 411) for the drain contacts 124 (not shown in FIG. 8). In addition, the second metal layer includes metal regions 412 (omitted from FIG. 9), each of which is connected to a respective corner of the hollow-square-shaped metal region 320 of the first metal layer. The metal regions 412 of the second metal layer form a part of the via stack 314 (including vias 414) for the “gate2” contacts 168 (not shown in FIG. 8), which are locally connected by the metal region 320 of the first metal layer, as noted above. The second metal layer is coupled to the metal region 320 of the first metal layer only at two of the four corners of the metal region 320. The other two corners of the metal region 320 are free to be crossed over by bridge regions 404 of the continuous region 400 of the second metal layer. No vias are present at those other two corners. (The metal regions 412 may be L-shaped in profile, as shown in FIG. 8, to aid in compliance with metallization design rules, or may be provided in profiles having other shapes.)

The layouts of the third, fourth and fifth metal layers are straightforward and need not be further described.

The provision of the metal region 320 in the hollow square configuration as shown in FIGS. 7 and 8, connected at less the all corners to the second metal layer, provides a number of advantages, including the following: (a) the metal region 320 shields nearby components, such as the “gate1”contacts and via stack from the drain via stack to reduce coupling from drain to “gate1”; (b) the metal region 320 serves as a local interconnect that allows the “gate2” contacts to be connected to an upper metal layer in fewer than four corners; and (c) the space at the corners not occupied by the “gate2” via stack can be used to allow interconnection (by way of bridge regions 404 of the second metal layer) of all of the “gate1” contacts of the cascode array structure.

The transistor cascode structure described above and its associated metallization scheme generally permit a very compact and space-efficient layout. Moreover, within the limits of design rules, the gate regions 142, 144, 146, 148, 150, 152, 156, 158 (FIG. 2) and the associated polysilicon gates 161 may be shifted toward the drain areas and away from the source areas to reduce the drain capacitance due to the smaller drain area and to reduce the source resistance due to the larger source area. The larger source area also allows more contacts to be placed in the source areas.

The transistor cascode structure described above is suitable for use in high frequency applications. In general, a signal fed into the gate of a MOSFET is affected by the series resistance R along the gate and by the capacitance C from the gate to the channel below the gate. These two parasitics cause an extra signal delay propagation proportional to R*C and the square of the channel width (which corresponds to the leg length of the gate polysilicon). This delay tends to degrade high-frequency performance of the transistor. However, the transistor cascode structure described herein minimizes the leg length of the transistor cells while maintaining a high total channel width per area. The short leg length also aids in achieving a low noise figure.

Space efficiency of the cascode structure is further enhanced by the fully integrated nature of the cells, in which no metal connection is required between the two transistors of each cascode, thereby also reducing parasitic capacitance and series resistance. Also, the shared diffusion regions by which the connection between the two transistors is made are fully shielded from the rest of the circuit and are therefore less vulnerable to injection of noise and interference.

Another advantage is that the aspect ratio of the cell array (i.e. selection of the numbers of rows and columns) may be freely chosen to aid in building matched cascode pairs and to facilitate space planning on the semiconductor die.

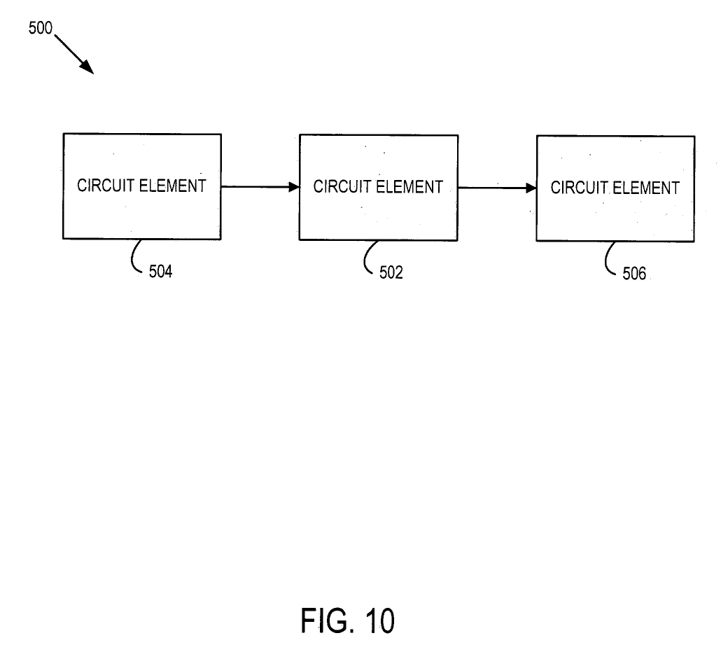

The transistor cascode structure described herein is particularly suitable for use in wireless and/or high frequency equipment. For example, the transistor cascode structure may be employed as a component in a low noise amplifier (LNA). FIG. 10 is a diagram that schematically illustrates a circuit 500 that incorporates the transistor cascode structure. The circuit 500 includes a circuit element 502, which may be a subcircuit that incorporates the transistor cascode structure of FIG. 4. Coupled to the circuit element 502 in an upstream direction is a circuit element 504, which may be, for example, a receiver component. Coupled to the circuit element 502 in a downstream direction is a circuit element 506, which may be, for example, a subsequent amplifier stage.

In another embodiment, the circuit element 502 may be a die that includes an integrated circuit of which the transistor cascode structure of FIG. 4 is a part. The circuit element 504 may be external to the die and may be, for example, an antenna. The circuit element 506 may also be external to the die and may be, for example, a speaker.

The several embodiments described herein are solely for the purpose of illustration. The various features described herein need not all be used together, and any one or more of those features may be incorporated in a single embodiment. Therefore, persons skilled in the art will recognize from this description that other embodiments may be practiced with various modifications and alterations.

What is claimed is:

1. A semiconductor cascode structure comprising a plurality of drain contacts located in a diffusion region that is substantially surrounded by a gate region.

2. The semiconductor cascode structure of claim 1, wherein the plurality of drain contacts includes four drain contacts.

3. The semiconductor cascode structure of claim 2, wherein no more than four drain contacts are located in the diffusion region.

4. The semiconductor cascode structure of claim 1, wherein the diffusion region is substantially square.

5. A semiconductor cascode structure comprising a plurality of source contacts located in a diffusion region that is substantially surrounded by a gate region.

6. The semiconductor cascode structure of claim 5, wherein the plurality of source contacts includes four source contacts.

7. The semiconductor cascode structure of claim 6, wherein twelve source contacts are located in the diffusion region.

8. The semiconductor cascode structure of claim 5, wherein the diffusion region is substantially square.

9. A semiconductor cascode structure comprising:
a plurality of source contacts located in a first diffusion region that is substantially surrounded by a first gate region; and
a plurality of drain contacts located in a second diffusion region that is substantially surrounded by a second gate region.

10. The semiconductor cascode structure of claim 9, wherein the first diffusion region is substantially square and the second diffusion region is substantially square.

11. The semiconductor cascode structure of claim 10, wherein the first diffusion region is larger than the second diffusion region.

12. The semiconductor cascode structure of claim 9, wherein the first diffusion region is larger than the second diffusion region.

13. The semiconductor cascode structure of claim 9, further comprising a third diffusion region located between the first gate region and the second gate region.

14. The semiconductor cascode structure of claim 13, wherein the first diffusion region is larger than the second diffusion region.

15. The semiconductor cascode structure of claim 14, wherein the third diffusion region is smaller than the second diffusion region.

16. The semiconductor cascode structure of claim 13, wherein a first transistor and a second transistor are formed by the structure, the third diffusion region being shared by a drain of the first transistor and a source of the second transistor.

17. The semiconductor cascode structure of claim 9, further comprising:
a first metal layer which includes:
a first metal region which interconnects the source contacts; and
a second metal region having a hollow rectangle as a profile, the hollow rectangle being coupled at each of its four corners to a respective second gate contact, each of the second gate contacts being coupled to the second gate region; and
a second metal layer that partially overlies the first metal layer and that is coupled through the first metal layer to a plurality of first gate contacts, each of the first gate contacts being coupled to the first gate region, the second metal layer being coupled to the second metal region of the first metal layer only at two of the four corners of the hollow rectangle.

18. The semiconductor cascode structure of claim 17, wherein the first metal layer further comprises a third metal region that interconnects the drain contacts, the third metal region being surrounded by the second metal region.

19. A transistor cascode cell, comprising:
a first diffusion region in a first quadrant of the cell;
a first drain contact located in the first diffusion region;
a second diffusion region in a second quadrant of the cell;
a first source contact located in the second diffusion region;
a third diffusion region located between the first diffusion region and the second diffusion region;
a fourth diffusion region in a third quadrant of the cell;
a second drain contact located in the fourth diffusion region;
a fifth diffusion region located between the second diffusion region and the fourth diffusion region;
a sixth diffusion region in a fourth quadrant of the cell;
a second source contact located in the sixth diffusion region;
a seventh diffusion region located between the fourth diffusion region and the sixth diffusion region; and
an eighth diffusion region located between the first diffusion region and the sixth diffusion region.

20. The transistor cascode cell of claim 19, further comprising:
a first gate region located in the first quadrant between the first diffusion region and the third diffusion region;
a second gate region located in the second quadrant between the second diffusion region and the third diffusion region;
a third gate region located in the second quadrant between the second diffusion region and the fifth diffusion region;
a fourth gate region located in the third quadrant between the fourth diffusion region and the fifth diffusion region;
a fifth gate region located in the third quadrant between the fourth diffusion region and the seventh diffusion region;
a sixth gate region located in the fourth quadrant between the sixth diffusion region and the seventh diffusion region;
a seventh gate region located in the fourth quadrant between the sixth diffusion region and the eighth diffusion region; and
an eighth gate region located in the first quadrant between the first diffusion region and the eighth diffusion region.

21. The transistor cascode cell of claim 20, further comprising:
an isolation region which overlaps a respective portion of each of the first, second, third and fourth quadrants;
a first gate contact located in the isolation region and in the first quadrant of the cell, and coupled to the first and eighth gate regions;
a second gate contact located in the isolation region and in the second quadrant of the cell, and coupled to the second and third gate regions;
a third gate contact located in the isolation region and in the third quadrant of the cell, and coupled to the fourth and fifth gate regions; and
a fourth gate contact located in the isolation region and in the fourth quadrant of the cell, and coupled to the sixth and seventh gate regions.

22. The transistor cascode cell of claim 21, wherein:
the first quadrant is an upper right-hand quadrant of the cell;
the second quadrant is a lower right-hand quadrant of the cell;
the third quadrant is a lower left-hand quadrant of the cell; and
the fourth quadrant is an upper left-hand quadrant of the cell.

23. The transistor cascode cell of claim 21, wherein:
the first and fourth diffusion regions are substantially equal in size to each other;
the second and third diffusion regions are substantially equal in size to each other; and
the second diffusion region is larger than the first diffusion region.

24. The transistor cascode cell of claim 23, wherein:
the third, fifth, seventh and eighth diffusion regions are all substantially equal in size to each other; and
the first diffusion region is larger than the third diffusion region.

25. The transistor cascode cell of claim 24, wherein:
the first, second, third, fourth, fifth, sixth, seventh and eighth gate regions are all substantially equal in size to each other; and
the third diffusion region is larger than the first gate region.

26. The transistor cascode cell of claim 19, wherein:
the first and fourth diffusion regions are substantially equal in size to each other;
the second and third diffusion regions are substantially equal in size to each other; and
the second diffusion region is larger than the first diffusion region.

27. The transistor cascode cell of claim 26, wherein:
the third, fifth, seventh and eighth diffusion regions are all substantially equal in size to each other; and
the first diffusion region is larger than the third diffusion region.

28. A circuit comprising:
a first circuit element that includes a cascode array; and
a second circuit element coupled to the first circuit element;
wherein the cascode array comprises:
a plurality of source contacts located in a first diffusion region that is substantially surrounded by a first gate region; and
a plurality of drain contacts located in a second diffusion region that is substantially surrounded by a second gate region.

29. The circuit of claim 28, wherein the first circuit element is part of an integrated circuit carried by a die, and the second circuit element is external to, and coupled to, the die.

30. The circuit of claim 28, wherein the first diffusion region is substantially square and the second diffusion region is substantially square.
